(19) United States
(12) Patent Application Publication
(10) Pub. No.: US 2018/0374717 A1
(43) Pub. Date: Dec. 27, 2018

(54) Semiconductor package and method of forming the same

(71) Applicant: POWERTECH TECHNOLOGY INC., Hsinchu County (TW)

(72) Inventors: Hung-Hsin Hsu, HSINCHU COUNTY (TW); Nan-Chun Lin, HSINCHU COUNTY (TW); Shang-Yu Chang Chien, HSINCHU COUNTY (TW)

(21) Appl. No.: 15/630,972

(22) Filed: Jun. 23, 2017

(51) Int. Cl. H01L 21/56; H01L 21/78; H01L 23/00; H01L 23/552

(52) U.S. Cl. CPC H01L 21/561; H01L 21/78; H01L 24/83; H01L 2924/37001; H01L 23/552; H01L 24/14; H01L 24/29

(57) ABSTRACT

An adhesive layer is formed on a semiconductor wafer. The semiconductor wafer is diced to form a plurality of chips. Each of the chips has an adhesive sheet diced from the adhesive layer. Adhesive sheets of the chips are adhered to a carrier. The chips and the carrier are encapsulated by a mold layer. The mold layer is grinded to form a grinded surface. An interconnection structure is formed on the grinded surface. A plurality of semiconductor packages are formed by sawing the mold layer and at least a polyimide layer of the interconnection structure.

### BACKGROUND OF THE INVENTION

### 1. Field of the Invention

The present invention relates to a field of packaging semiconductor chips, and more particularly to a method of forming a fan-out semiconductor package.

### 2. Description of the Prior Art

Wafer level packaging process is known in the art. In a wafer level packaging process, a wafer with integrated circuits mounted thereon undergoes a series of process, such as grinding, die-bonding, molding and so on, and is finally cut into finished products. Wafer level packaging process has been considered as suitable technology for small sized and high-speed package. However, the die shift caused by a drag force of the epoxy molding compound (EMC) is usually an important issue for the wafer level packaging process because it deteriorates the quality of the final product.

### SUMMARY OF THE INVENTION

An embodiment of the present invention provides a method for forming a semiconductor package. The method comprises providing a semiconductor wafer; forming an adhesive layer on a surface of the semiconductor wafer; dicing the semiconductor wafer to form a plurality of chips, each of the chips having a plurality of pillar bumps and an adhesive sheet diced from the adhesive layer; adhering the adhesive sheet of each of the chips to a first surface of a carrier; forming a mold layer to encapsulate the chips and the carrier; grinding at least the mold layer to expose the pillar bumps and forma grinded surface; forming an interconnection structure containing circuitries on the grinded surface, each of the circuitries being electrically connected to pillar bumps of a corresponding chip; and forming a plurality of semiconductor packages by sawing the mold layer and at least a polyimide layer of the interconnection structure. Each of the semiconductor packages comprises at least one of the chips and a corresponding circuitry.

Another embodiment of the present invention provides a semiconductor package. The semiconductor package comprises a carrier, at least a chip, a mold layer and an interconnection structure. The chip is adhered on a first surface of the carrier by an adhesive sheet. The chip has a plurality of pillar bumps. The mold layer encapsulates the chip and the carrier. The interconnection structure is formed on a grinded surface of the mold layer and is electrically connected to the pillar bumps of the chip.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 14 are component cross-sectional views showing corresponding processing steps of the method according to a first embodiment of the present invention.

FIGS. 15 to 18 are component cross-sectional views showing corresponding processing steps of the method according to a second embodiment of the present invention.

FIGS. 19 to 32 are component cross-sectional views showing corresponding processing steps of the method according to a third embodiment of the present invention.

FIG. 33 is a component cross-sectional view of a semiconductor package manufactured according to a fourth embodiment of the present invention.

FIG. 34 is a component cross-sectional view of a semiconductor package manufactured according to a fifth embodiment of the present invention.

FIG. 35 is a component cross-sectional view of a semiconductor package manufactured according to a sixth embodiment of the present invention.

### DETAILED DESCRIPTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

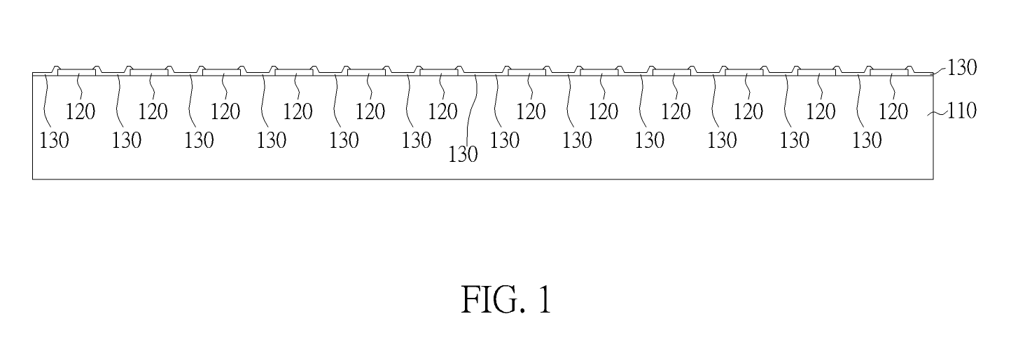

According to a first embodiment of the present invention, a method of forming a semiconductor package is illustrated in FIGS. 1 to 14 using cross-sectional views.

As shown in FIG. 1, a semiconductor wafer 110 is provided. The semiconductor wafer 110 may have a plurality of conductive pads 120 and an insulation layer 130. The insulation layer 130 may be formed on an active surface of the semiconductor wafer 110. The conductive pads 120 may be formed in the openings of the insulation layer 130. The conductive pads 120 may be electrically connected to integrated circuits (ICs) formed in the semiconductor wafer 110.

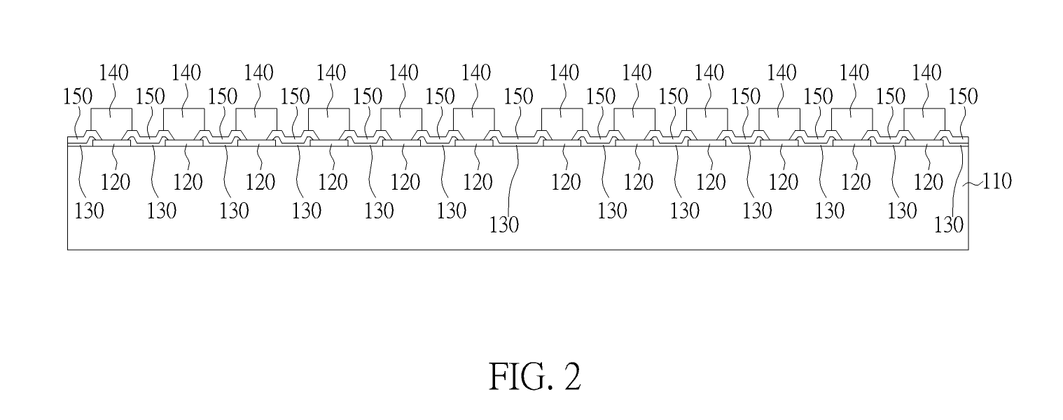

As shown in FIG. 2, a plurality of pillar bumps 140 may be formed on the conductive pads 120. A dielectric layer 150 may be formed on the insulation layer 130. The height of the pillar bumps 140 may be greater than the height of the dielectric layer 150. The pillar bumps 140 may be of copper (Cu), gold (Au) or a copper alloy. The dielectric layer 150 may be of polyimide (PI).

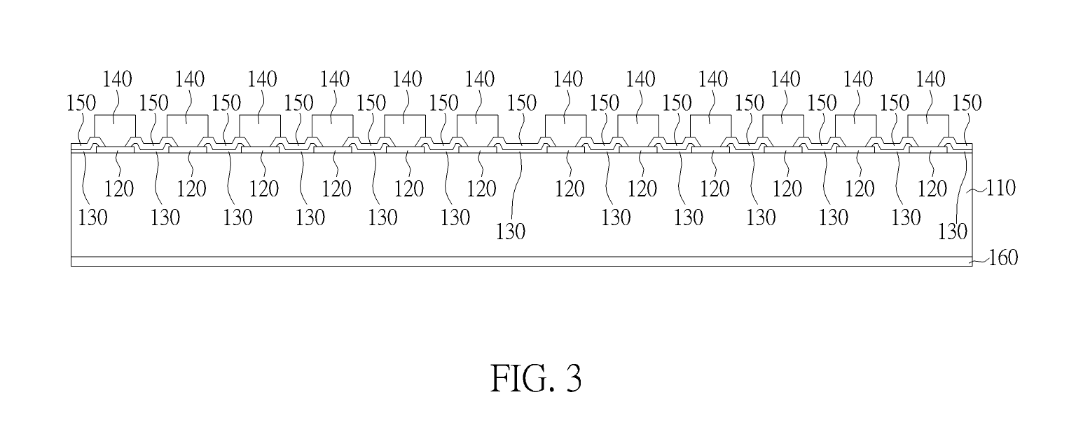

As shown in FIG. 3, an adhesive layer 160 may be formed on the lower side of the semiconductor wafer 110 by performing a coating process, a screen printing process, a stencil printing or a lamination process. The adhesive layer 160 may be with good adhesion to silicon. The adhesive layer 160 may be a B-stage material, epoxy, silicone, and/or Ajinomoto build-up film (ABF).

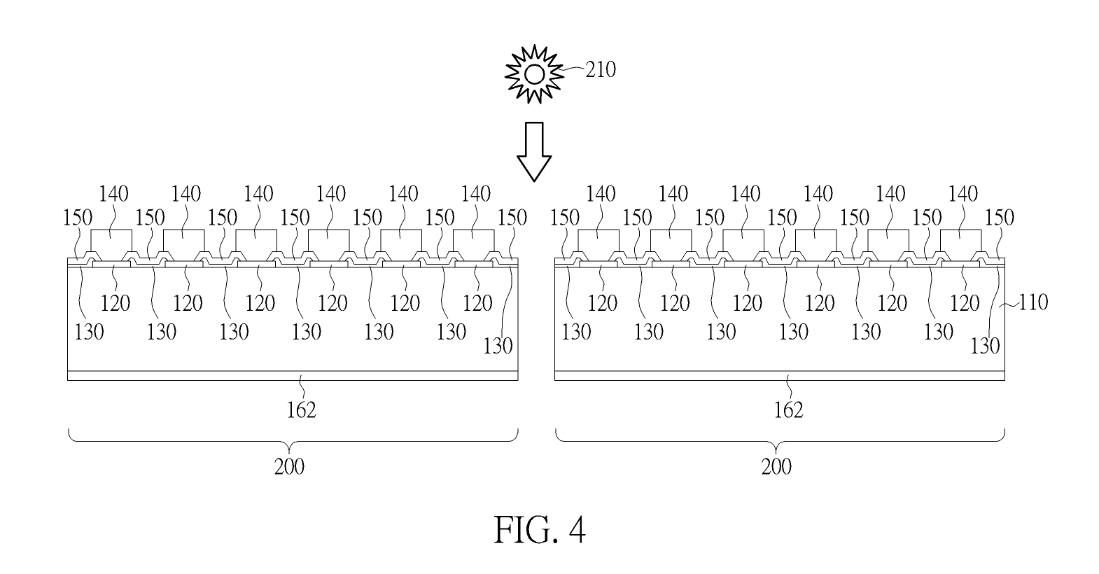

As shown in FIG. 4, after the adhesive layer 160 is formed on the lower side of the semiconductor wafer 110, a dicing mechanism 210 may be used to dice the semiconductor wafer 110 to form a plurality of chips 200. Each of the chips 200 may include a number of the pillar bumps 140 and an adhesive sheet 162 diced from the adhesive layer 160.

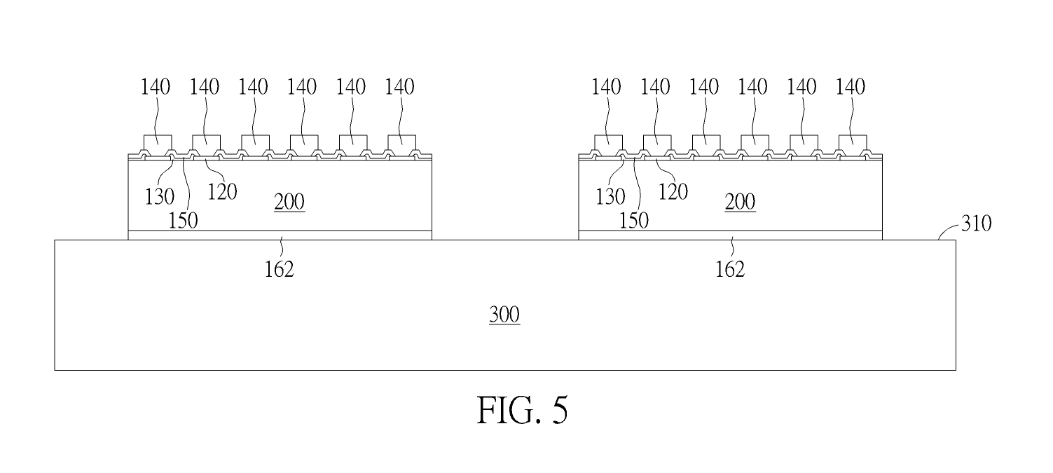

As shown in FIG. 5, the chips 200 may be permanently disposed on a first surface 310 of a carrier 300 by permanently adhering the adhesive sheet 162 of each of the chips 200 to the first surface 310 of the carrier 300. The carrier 300 does not in itself perform any electrical function (i.e., delivering voltage or current). The carrier 300 may be of glass, silicon, and/or a material with a coefficient of thermal expansion (CTE) close to that of the semiconductor wafer 110. The carrier 300 may have a thermal conductivity greater than that of the semiconductor wafer 110. A carrying area of the carrier 300 for supporting the chips 200 may be of a square shape, a rectangular shape or a circular shape. When the chips 200 are disposed on the first surface 310 of the carrier 300, the adhesive sheets 162 of the chips 200 may be cured to fasten the chips 200 on the first surface 310 of the carrier 300. Accordingly, the chips 200 would not shift during subsequent molding process. The adhesive sheets 162 may be removed subsequently from the chips 200 by performing a mechanical grinding and polishing process or a chemical mechanical polishing (CMP) process.

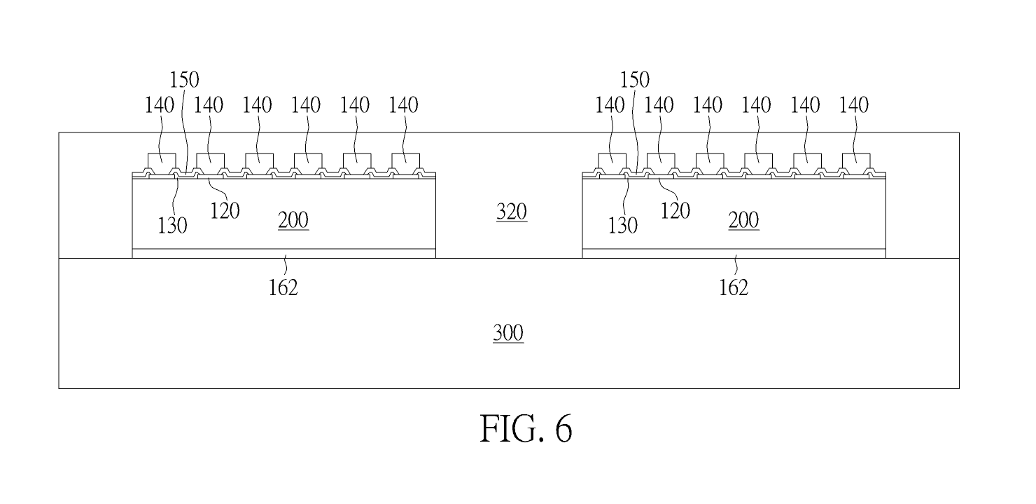

As shown in FIG. 6, a molding process may be performed to form a mold layer 320 to encapsulate the chips 200 and the carrier 300 after the adhesive sheet 162 of each of the chips 200 is adhered to the first surface 310 of the carrier 300. The mold layer 320 may be of epoxy molding compound (EMC). Because the chips 200 may be fixed on the first surface 310 of the carrier 300 by the cured adhesive sheets 162, and CTE of the carrier 300 and bodies of the chips 200 with the adhesive sheets 162 attached thereon may be almost the same, the chips 200 on the first surface 310 may not be moved by the drag force of the molding compound when the mold layer 320 is formed. Accordingly, compensation for position shift of the chips 200 may be substantially omitted, thus, enhancing precision of a subsequent lithography process.

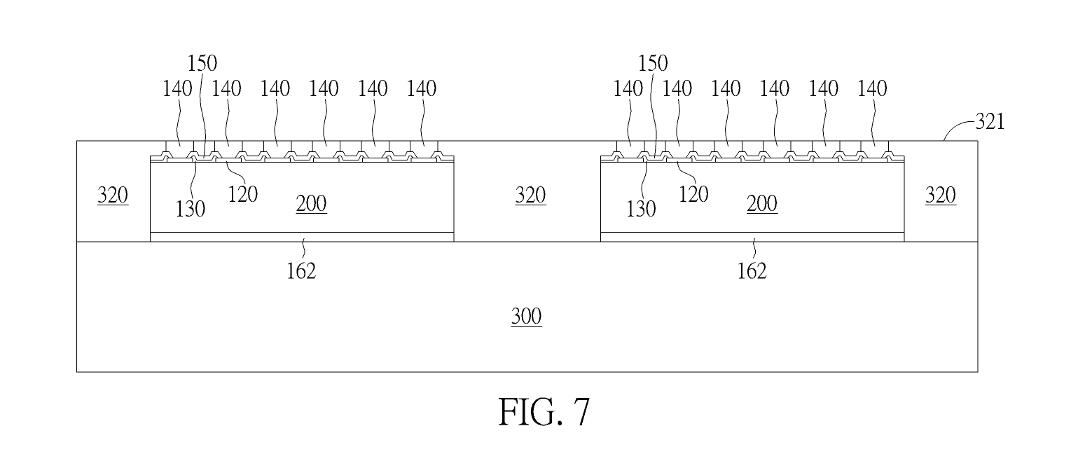

As shown in FIG. 7, the mold layer 320 may be grinded to expose the pillar bumps 140 and form a grinded surface 321.

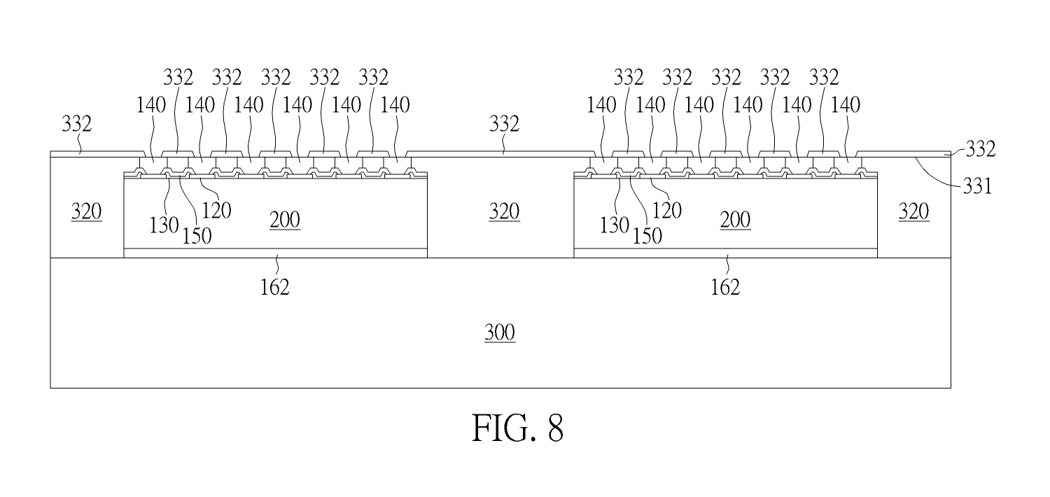

As shown in FIG. 8, a polyimide (PI) layer 332 may be formed on the grinded surface 321 of the mold layer 320 with the pillar bumps 140 exposed.

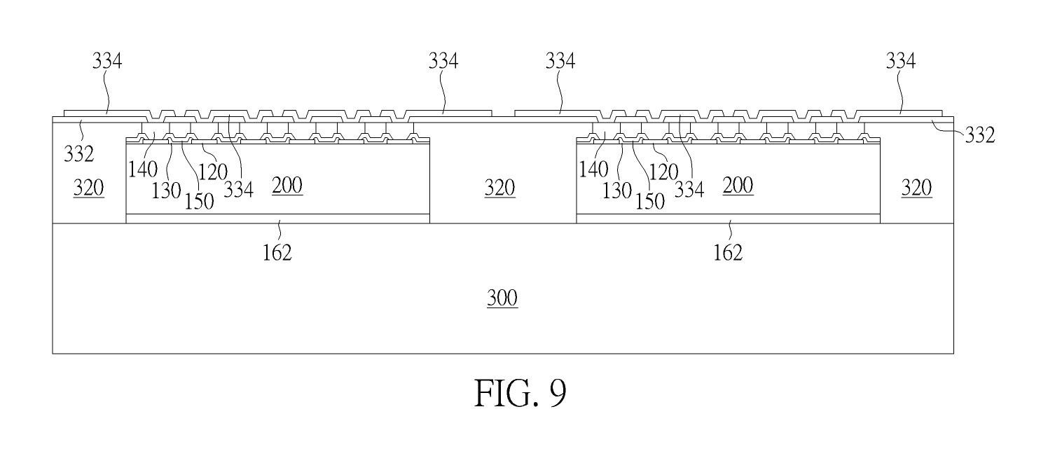

As shown in FIG. 9, a redistribution layer (RDL) 334 may be formed on the PI layer 332 and the pillar bumps 140. The redistribution layer (RDL) 334 may be electrically connected to the pillar bumps 140. There may be more than one RDL 334 depending on the complexity of the circuitry of the final semiconductor package.

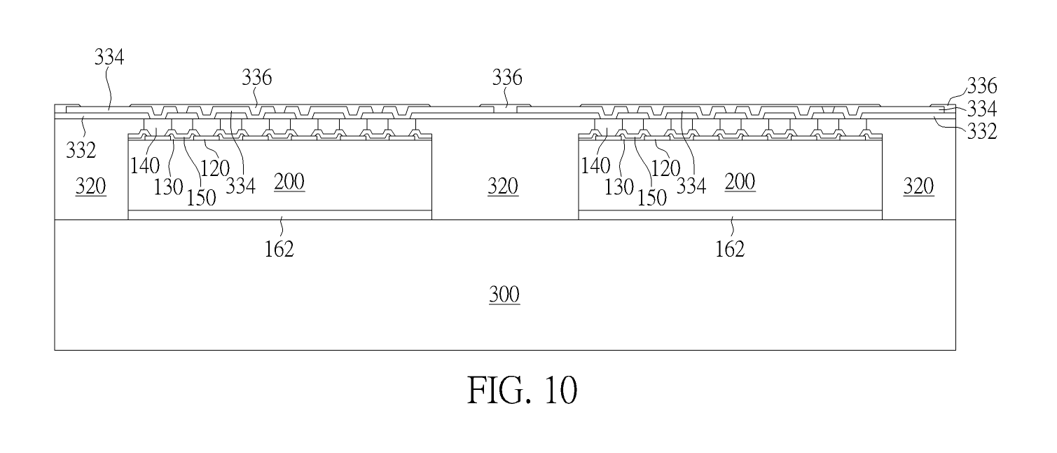

As shown in FIG. 10, another PI layer 336 may be formed on the RDL 334 with some portions of the RDL 334 exposed.

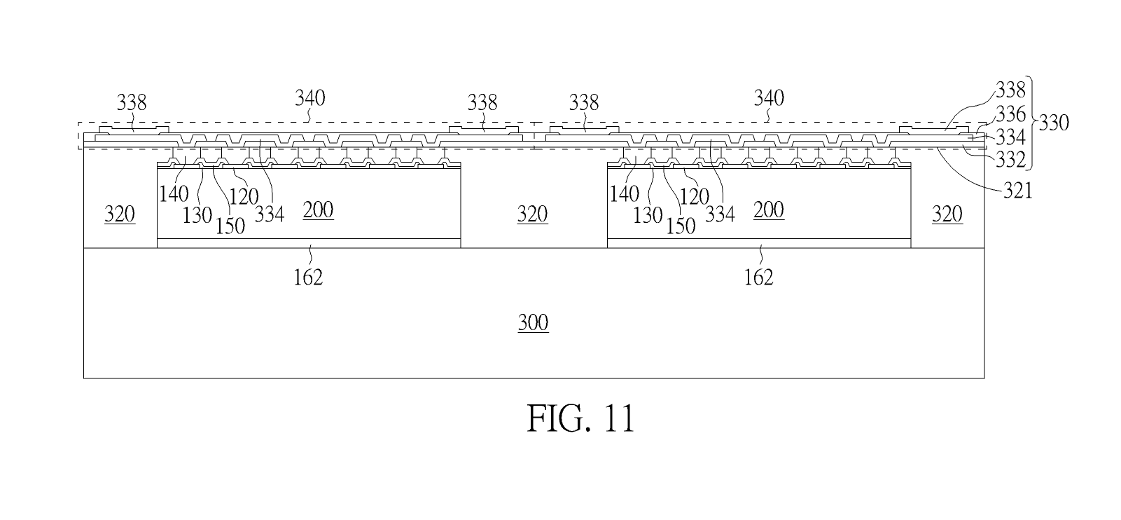

As shown in FIG. 11, an under bump metallization (UBM) layer 338 may be formed on the PI layer 336 and portions of the RDL 334 exposed by through the PI layer 336. According, an interconnection structure 330 including the PI layer 332, the RDL 334, the PI layer 336 and the UBM layer 338 may be formed on the grinded surface 321 of the mold layer 320. The interconnection structure 330 comprises a plurality of circuitries 340. Each of the circuitries 340 is electrically connected to the pillar bumps 140 of a corresponding chip 200.

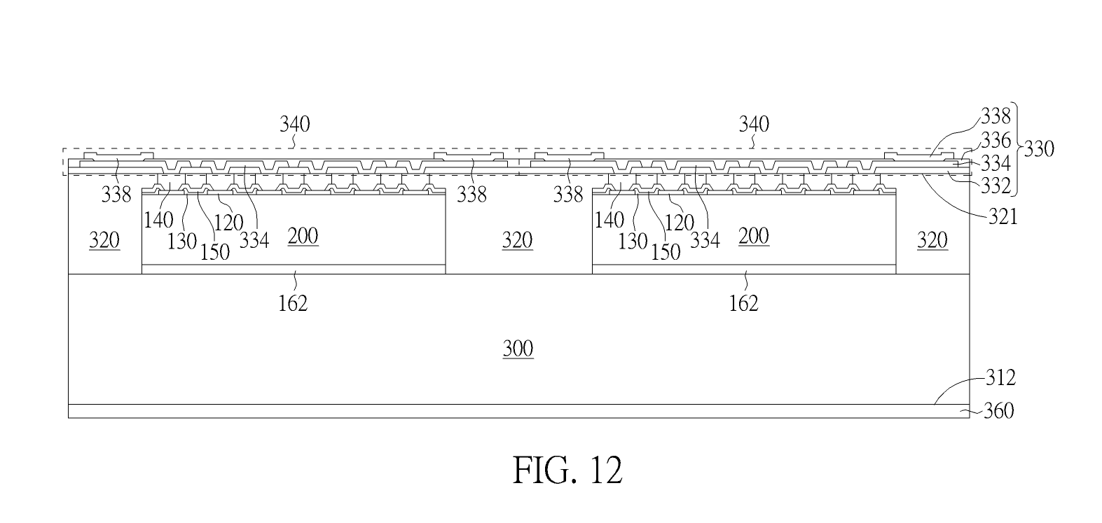

As shown in FIG. 12, a cover layer 360 may be formed on a second surface 312 of the carrier 300. The cover layer 360 may be formed by performing a screen printing process, a stencil printing or a lamination process. The cover layer 360 may be made of epoxy, silicone, Ajinomoto build-up film (ABF), backside coating tape (LC tape), or other materials with good adhesion to silicon and compatible to a subsequent laser marking process for forming package orientation marks and device information on the cover layer 360. With the cover layer 360, chipping and cracking can be avoided during a package singulation step. Moreover, the cover layer 360 can reduce the package warpage caused by the mold layer 320, the PI layers 332 and 336 and the RDL layer 334. In an embodiment of the present invention, the carrier 300 may be thinned before forming the cover layer 360 to reduce the thickness of the final semiconductor package.

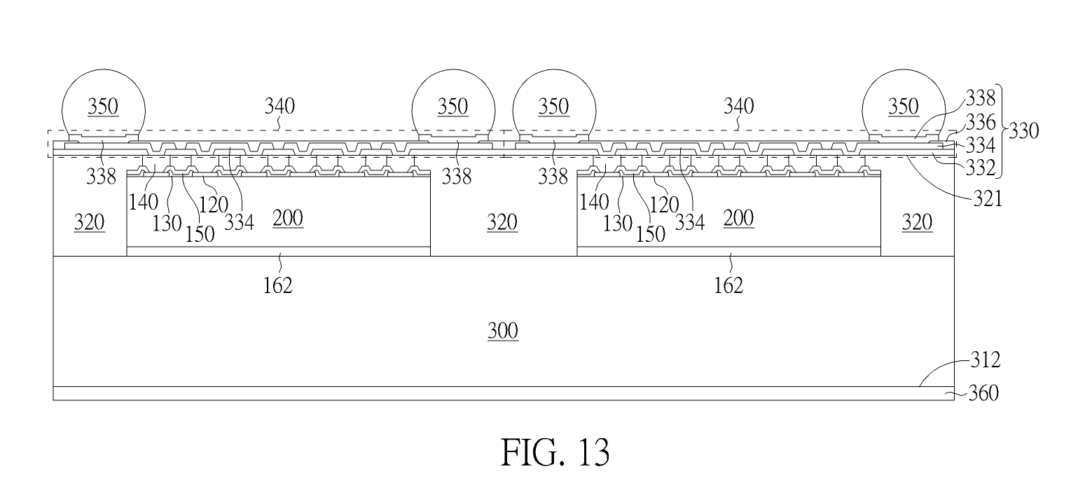

As shown in FIG. 13, a plurality of solder balls 350 may be formed on the circuitries 340 of the interconnection structure 330. In detail, the solder balls 350 may be formed on the UBM layer 338 and electrically connected to the pillar bumps 140 via the circuitries 340.

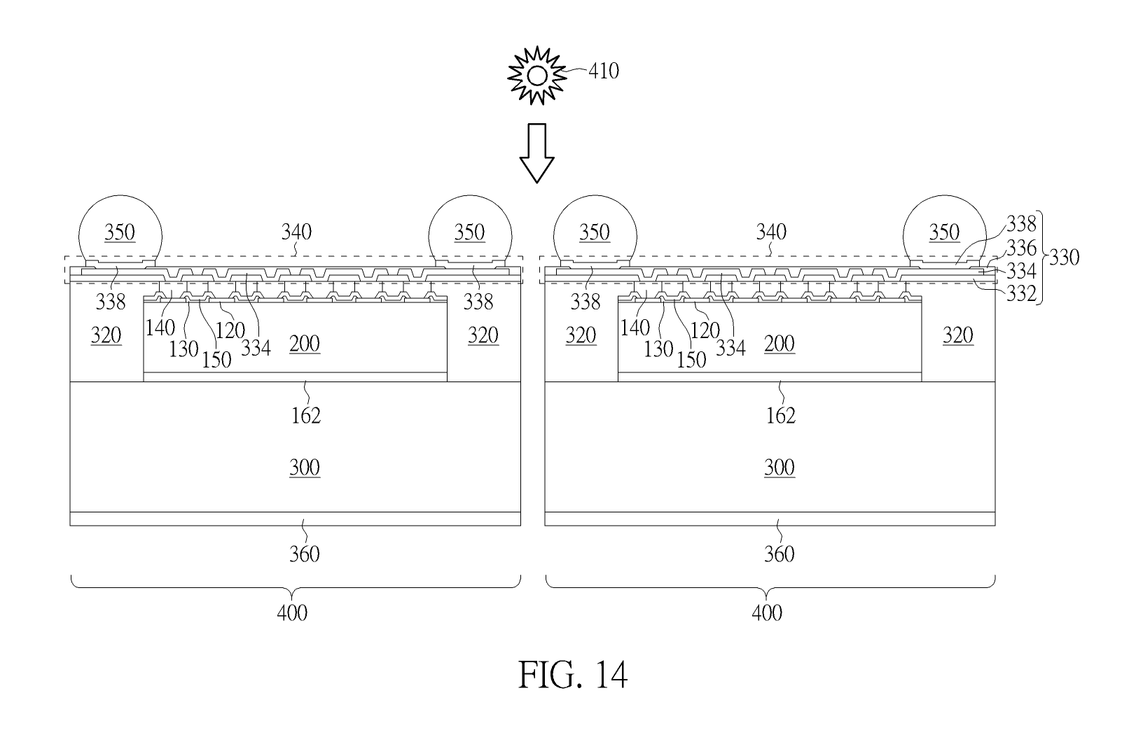

As shown in FIG. 14, a sawing mechanism. 410 may be used to saw the PI layers 332 and 336 of the interconnection structure 330, the mold layer 320, the carrier 300 and the cover layer 360 to form a plurality of semiconductor packages 400. Each of the semiconductor packages 400 comprises at least one of the chips 200 and a corresponding circuitry 340. Each semiconductor package 400 is a fan-out package, but the present invention is not limited thereto.

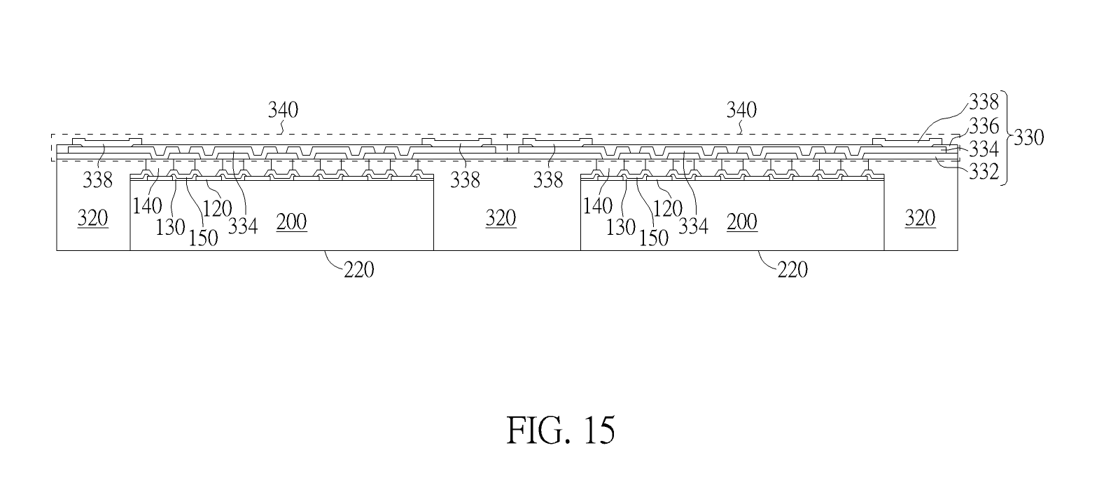

FIGS. 15 to 18 are cross-sectional views showing processing steps of the method according to a second embodiment of the present invention.

As shown in FIG. 15, the carrier 300 and the adhesive sheets 162 may be removed before the sawing mechanism 410 is used but after the interconnection structure 330 is formed. The carrier 300 may be removed by performing a dry etching process, a wet etching process, a grinding process, polishing process or a chemical mechanical polishing (CMP) process. The adhesive sheets 162 may be removed by performing a mechanical grinding process, polishing process, a CMP process, or a selective etching process. The carrier 300 may be grinded off, either a portion or completely. If the carrier 300 is grinded off completely, the adhesive sheets 162 and further a part of the chip 200 may be also grinded to reduce the thickness of the final semiconductor package. In the embodiment, the carrier 330 is grinded to expose inactive surfaces 220 of the chips 200. The inactive surfaces 220 are opposite to the interconnection structure 330.

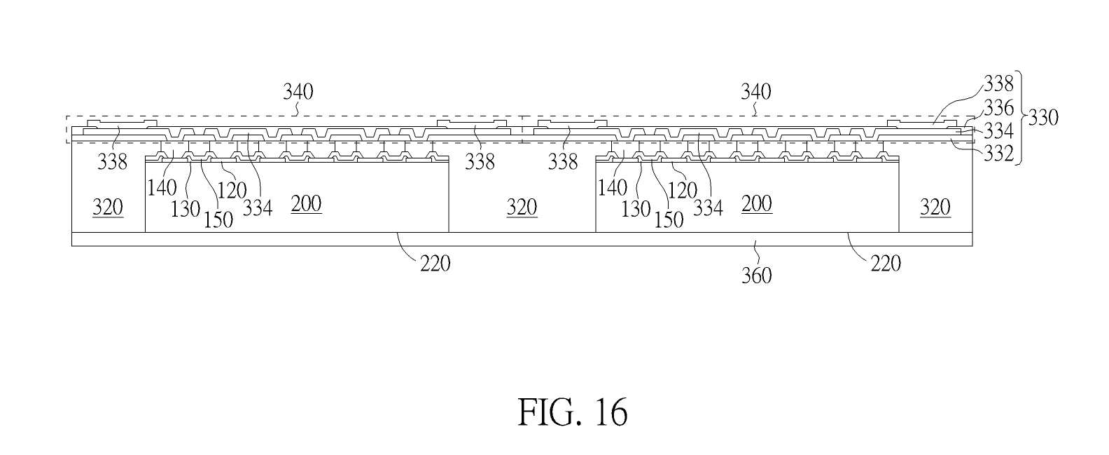

As shown in FIG. 16, after the carrier 300 and the adhesive sheets 162 are removed, the cover layer 360 may be formed above the chips 200 and opposite to the interconnection structure 330.

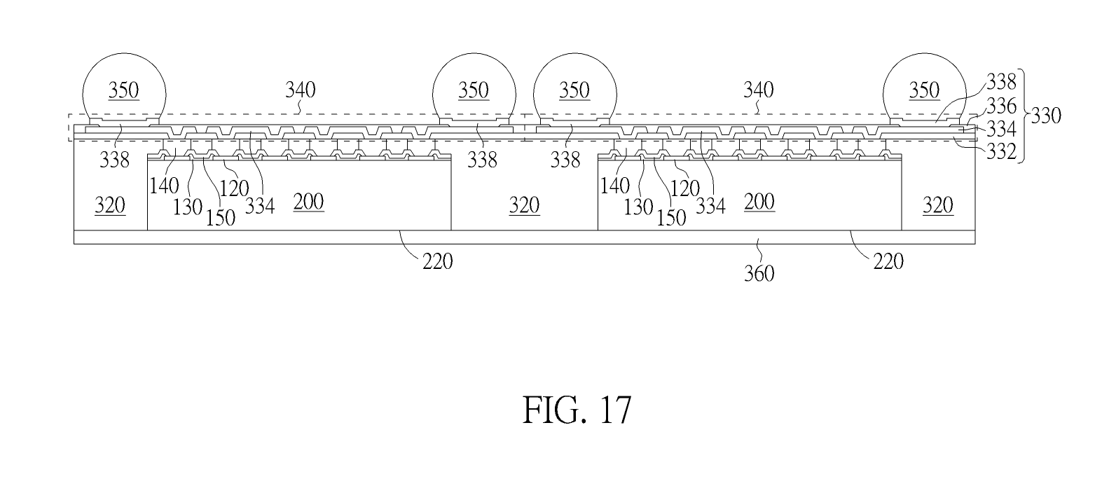

As shown in FIG. 17, the solder balls 350 may be formed on the circuitries 340 of the interconnection structure 330. In detail, the solder balls 350 may be formed on the UBM layer 338 and electrically connected to the pillar bumps 140 via the circuitries 340.

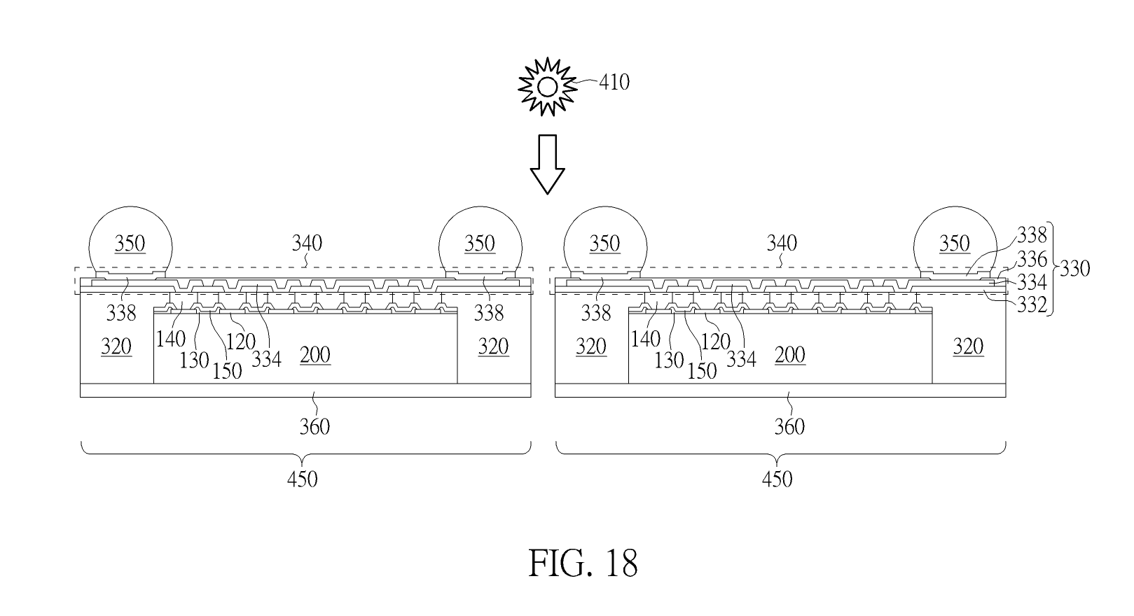

As shown in FIG. 18, the sawing mechanism 410 may be used to saw the PI layers 332 and 336 of the interconnection structure 330, and the mold layer 320 to form a plurality of semiconductor packages 450. The sawing mechanism 410 may further be used to saw the cover 360. Each of the semiconductor packages 450 comprises at least one of the chips 200 and a corresponding circuitry 340. Each semiconductor package 450 is a fan-out package, but the present invention is not limited thereto.

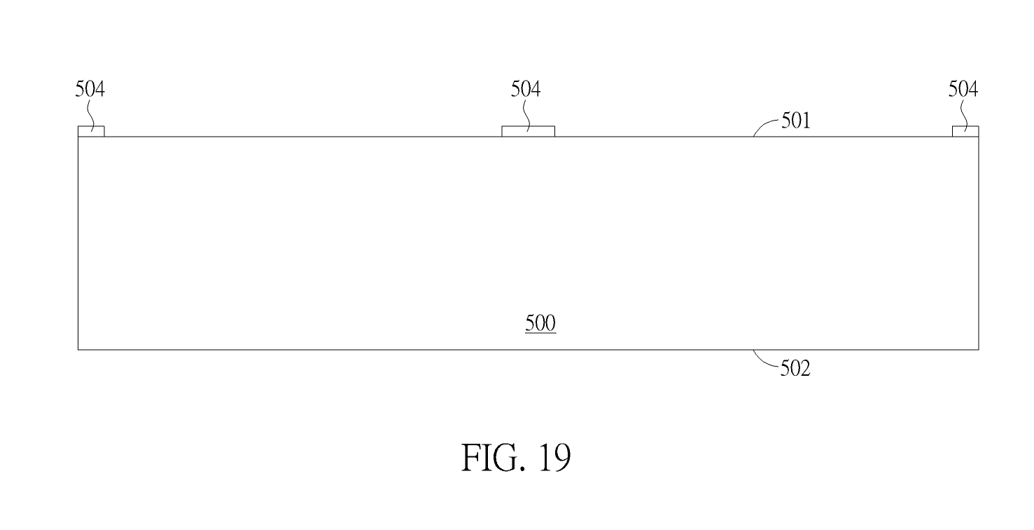

According to a third embodiment of the present invention, another method of forming a semiconductor package is illustrated in FIGS. 19 to 32 using cross-sectional views. The same reference numbers used in the first embodiment and the third embodiment represent the same elements.

As shown in FIG. 19, a substrate 500 is provided. The substrate 500 may be of silicon. A photoresist 504 may be formed on a first surface 501 of the substrate 500. The photoresist 504 is used as an etching mask for resisting subsequent wet chemical etching or plasma etching to achieve selective etching. The photoresist 504 may be formed by performing a coating process, a screen printing process, a stencil printing or a lamination process. In addition, the photoresist 504 may be removed by using acid, base or solvent after the substrate 500 is etched.

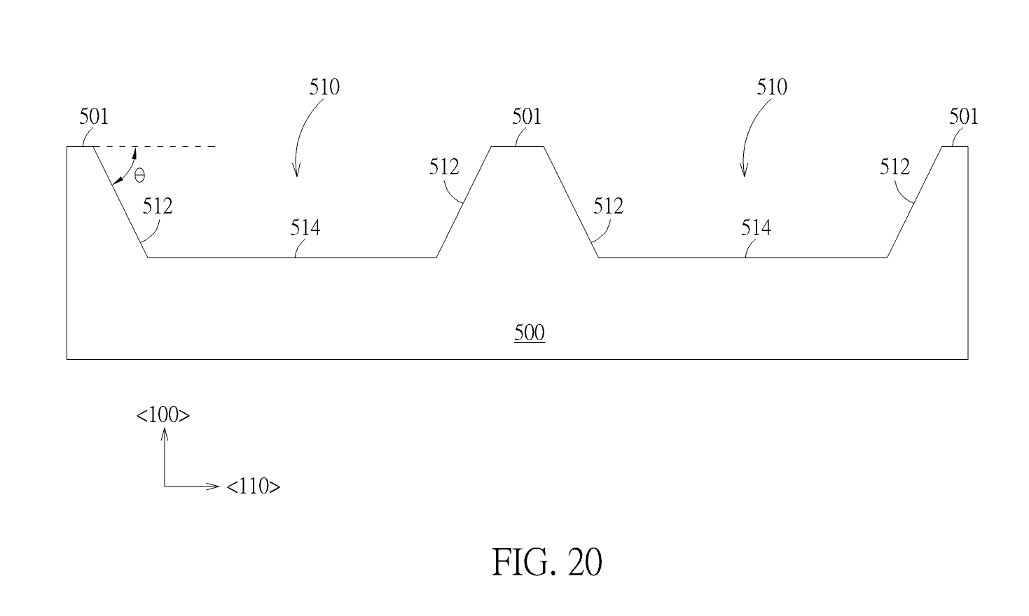

As shown in FIG. 20, a plurality of cavities 510 are formed on the first surface 501 of the substrate 500. In the embodiment, the substrate 500 is a silicon wafer, and the cavities 510 may be formed by performing a wet chemical etching process. In another embodiment, the cavities 510 may be formed by performing a plasma etching process. When the wet chemical etching is performed, the walls 512 of the cavities 510 would slope towards the bottoms 514 of the cavities 510. In some embodiment, an angle θ between the first surface 501 and the walls 512 of the cavities 510 may range from 50 to 60 degrees. As shown in FIG. 20, the first surface 501 and the bottoms 514 are parallel with <110> plane of the substrate 500 and perpendicular to <100> plane of the substrate 500. The walls 512 of the cavities 510 are <111> planes of the substrate 500.

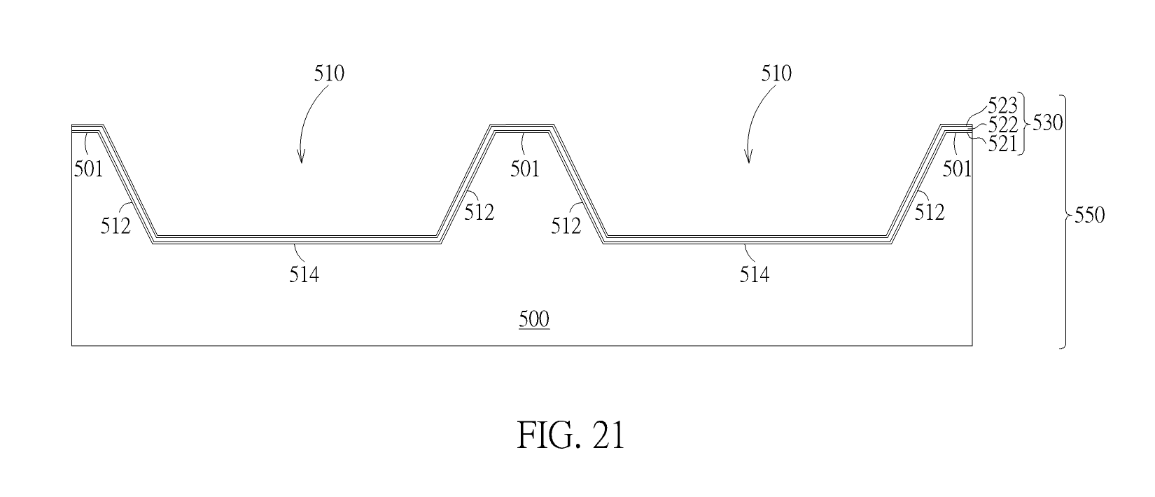

As shown in FIG. 21, a continuous electromagnetic interference (EMI) protection layer 530 may be formed on the substrate 500 to cover the walls 512 and the bottoms 514 of the cavities 510. The EMI protection layer 530 may be formed on the substrate 500 by performing physical vapor deposition (PVD). The EMI protection layer 530 may comprise three metal layers 521, 522 and 523, and the metal layer 522 is formed between the metal layer 521 and the metal layer 523. In an embodiment, the metal layers 521 and 523 may be of titanium (Ti), and the metal layer 522 may be of copper (Cu). In another embodiment, the metal layers 521 and 523 may be of stainless steel (SUS), and the metal layer 522 may be of copper (Cu). In addition, fiducial marks may be formed on the EMI protection layer 530 for subsequent alignment when bonding the chips 200 on the EMI protection layer 530. The subsequent alignment may include global alignment and/or local alignment. The substrate 500 and the EMI protection layer 530 constitute a carrier 550 for carrying the chips 200.

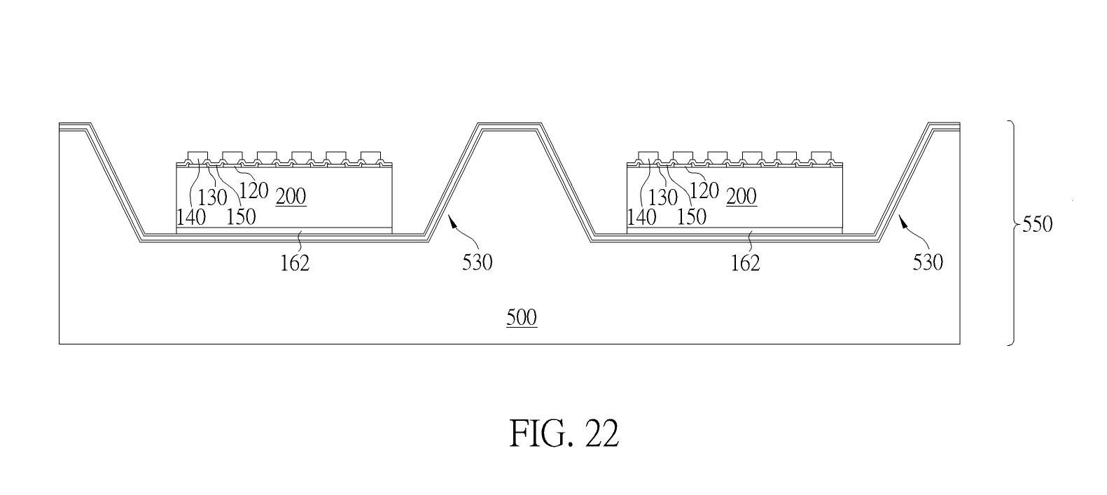

As shown in FIG. 22, the chips 200 may be permanently disposed in the cavities 510 by permanently adhering the adhesive sheets 162 of the chips 200 to the continuous EMI protection layer 530 of the carrier 550. The chips 200 illustrated in FIG. 22 may be manufactured based on the steps illustrated in FIG. 1 to FIG. 4. When the chips 200 are disposed in the cavities 510, the adhesive sheets 162 of the chips 200 may be cured to fasten the chips 200 on the EMI protection layer 530. Accordingly, the chips 200 would stay attached on the EMI protection layer 530 during a subsequent molding process.

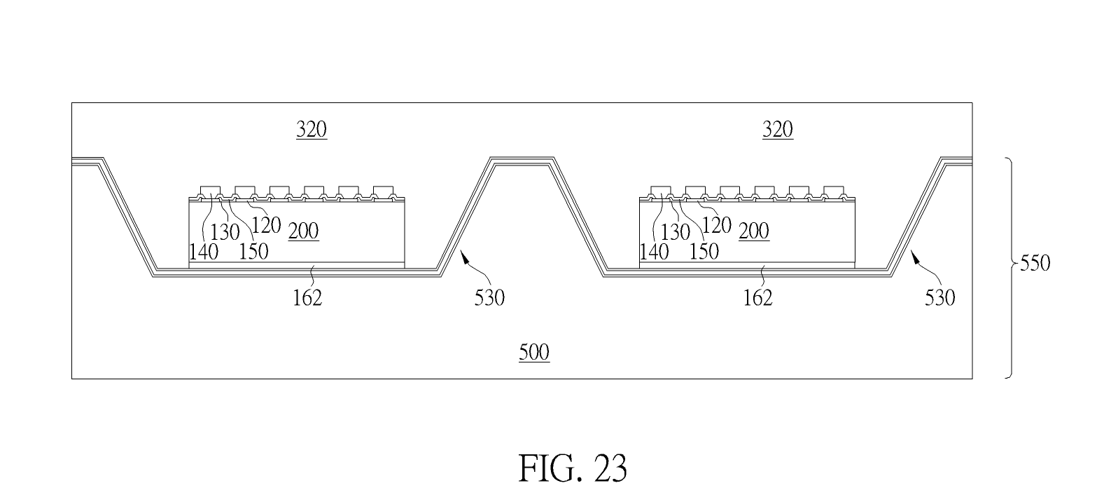

As shown in FIG. 23, a molding process may be performed to form the mold layer 320 to encapsulate the chips 200 and the carrier 550 after the adhesive sheets 162 of the chips 200 are adhered to the continuous EMI protection layer 530 of the carrier 550. Since the chips 200 may be fixed on the EMI protection layer 530 by the cured adhesive sheets 162. The CTE of the substrate 500 and bodies of the chips 200 with the adhesive sheets 162 attached thereon may be substantially the same. The chips 200 on the EMI protection layer 530 may not be moved by the drag force of the molding compound when the mold layer 320 is formed. Accordingly, compensation for position shift of the chips 200 may be omitted, thus, enhancing precision of a subsequent lithography process.

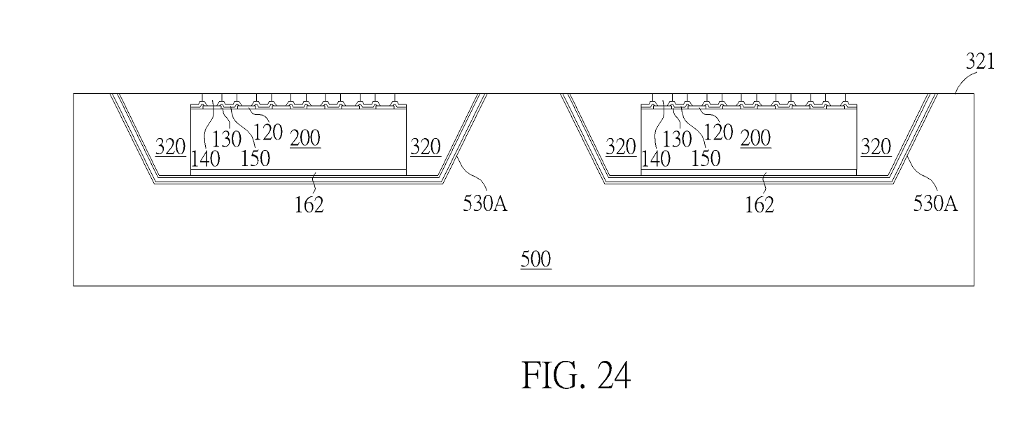

As shown in FIG. 24, the mold layer 320 may be grinded to expose the pillar bumps 140 and form a grinded surface 321. In some embodiments, parts of the EMI protection layer 530 and the substrate 500 may also be removed in the same grinding process. After parts of the EMI protection layer 530 and the substrate 500 are grinded, the EMI protection layer 530 is divided into a plurality of EMI shields 530A.

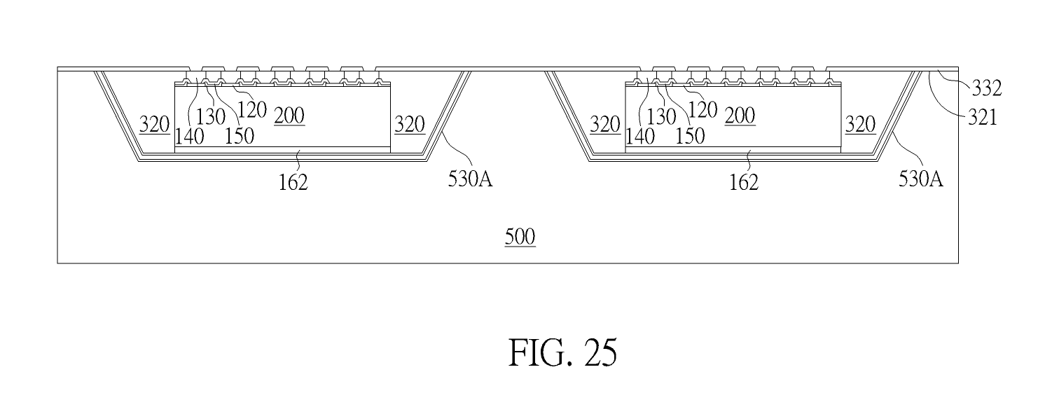

As shown in FIG. 25, the PI layer 332 may be formed on a grinded surface 321. The grinded surface 321 may include surfaces of the mold layer 320, the EMI protection layer 530, the substrate 500, and the pillar bumps 140 coplanar to each other.

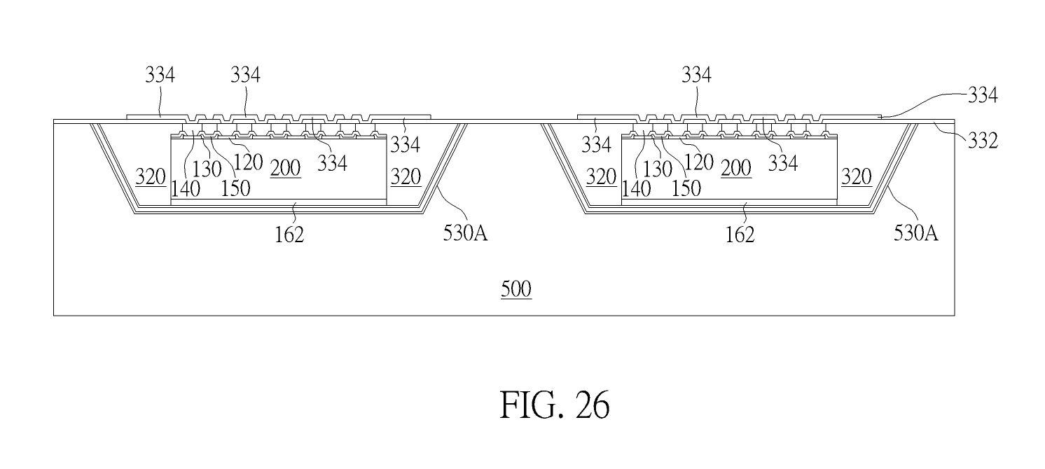

As shown in FIG. 26, the RDL 334 may be formed on the PI layer 332 and the pillar bumps 140. There may be more than one RDL 334 depending on the complexity of the circuitry of the final semiconductor package.

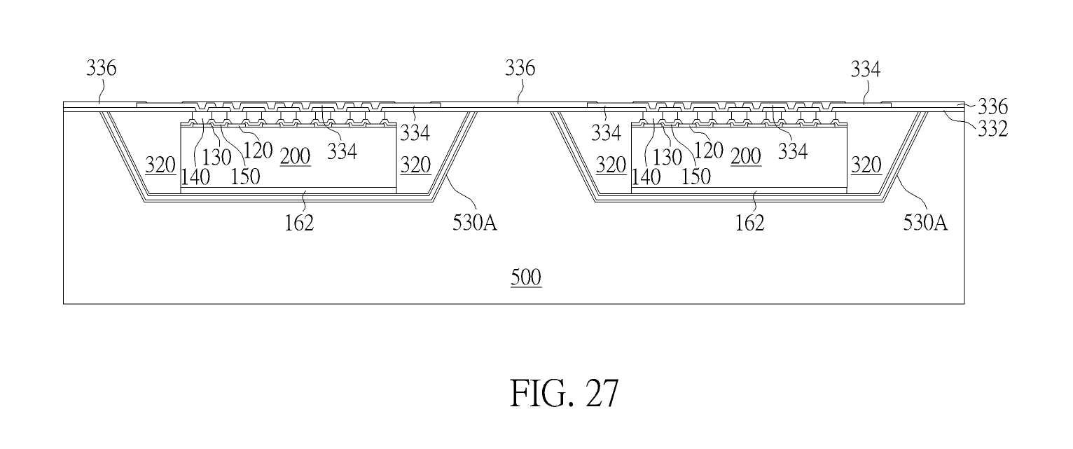

As shown in FIG. 27, the PI layer 336 may be formed on the RDL 334 with some portions of the RDL 334 exposed.

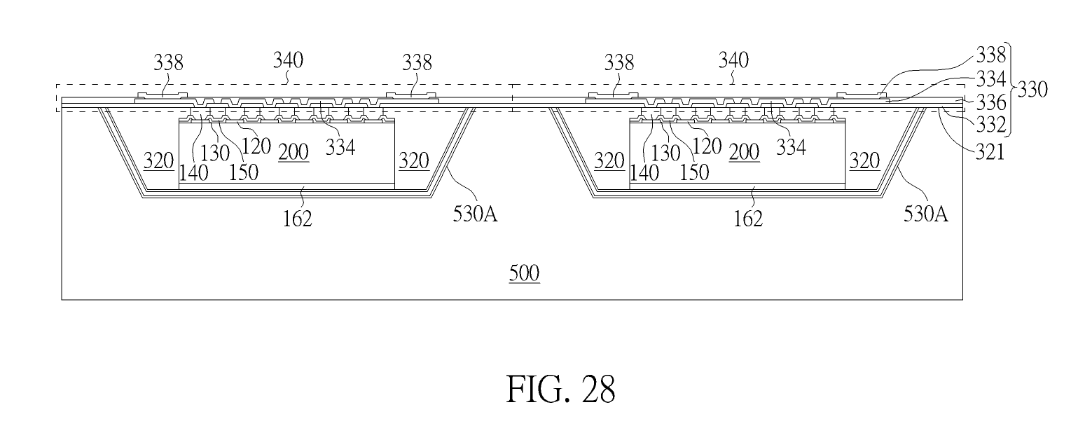

As shown in FIG. 28, the UBM layer 338 may be formed on the PI layer 336 and portions of the RDL 334. According, the interconnection structure 330 containing the PI layer 332, the RDL 334, the PI layer 336 and the UBM layer 338 may be formed on the grinded surface 321. The interconnection structure 330 contains a plurality of circuitries 340, and each of the circuitries 340 is electrically connected to the pillar bumps 140 of a corresponding chip 200.

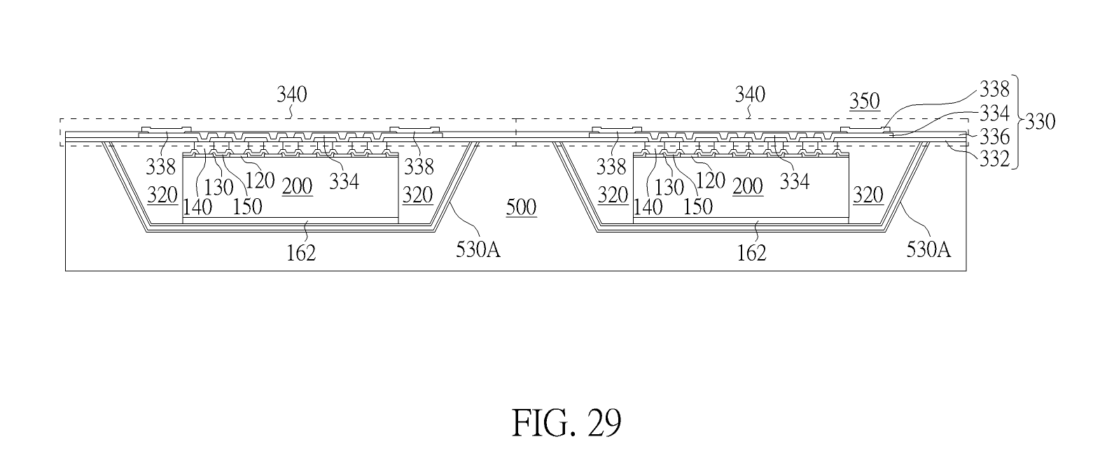

As shown in FIG. 29, a thinning process may be performed to thin the substrate 500. The thinning process may be a grinding process or an etching process.

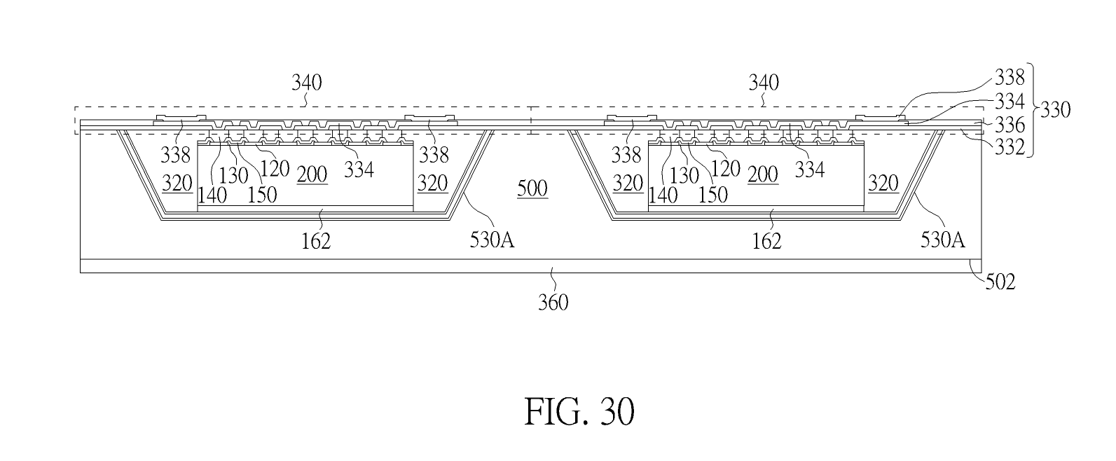

As shown in FIG. 30, the cover layer 360 may be formed on a second surface 502 of the substrate 500. The cover layer 360 may be formed by performing a screen printing process, a stencil printing or a lamination process, and the cover layer 360 may be of epoxy, silicone, Ajinomoto build-up film (ABF), backside coating tape (LC tape), or other materials with good adhesion to silicon and compatible to a subsequent laser marking process for forming package orientation marks and device information on the cover layer 360. With the cover layer 360, chipping and cracking can be avoided during a package singulation step. Moreover, the cover layer 360 can reduce the package warpage caused by the mold layer 320, the PI layers 332 and 336 and the RDL layer 334.

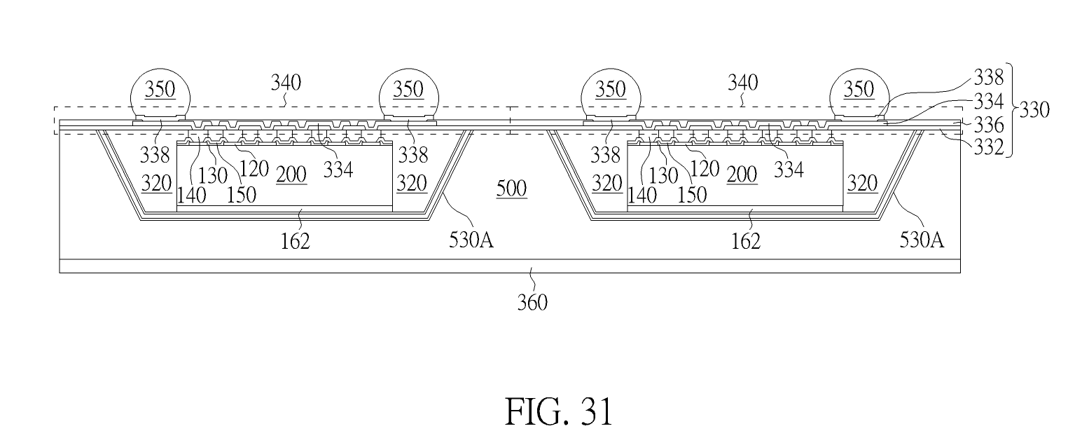

As shown in FIG. 31, the solder balls 350 may be formed on the circuitries 340 of the interconnection structure 330. In detail, the solder balls 350 may be formed on the UBM layer 338 and electrically connected to the pillar bumps 140 via the circuitries 340.

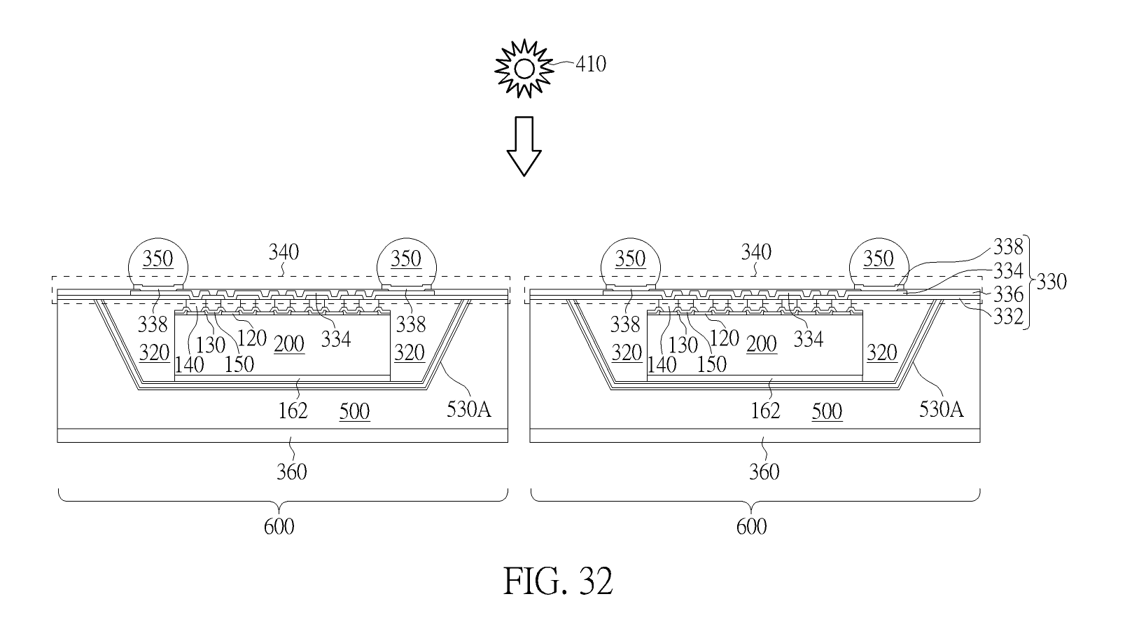

As shown in FIG. 32, the sawing mechanism 410 may be used to saw at least the interconnection structure 330 and the substrate 500 to forma plurality of semiconductor packages 600. In some embodiments, the PI layers 332 and 336 of interconnection structure 330 may be sawed through by the sawing mechanism 410. Each of the semiconductor packages 600 comprises a corresponding chip 200, one of the EMI shields 530A for providing EMI protection, a portion of the substrate 500 and a corresponding circuitry 340 electrically connected to the pillar bumps 140 of the corresponding chip 200. Each semiconductor package 600 is a fan-out package, but the present invention is not limited thereto.

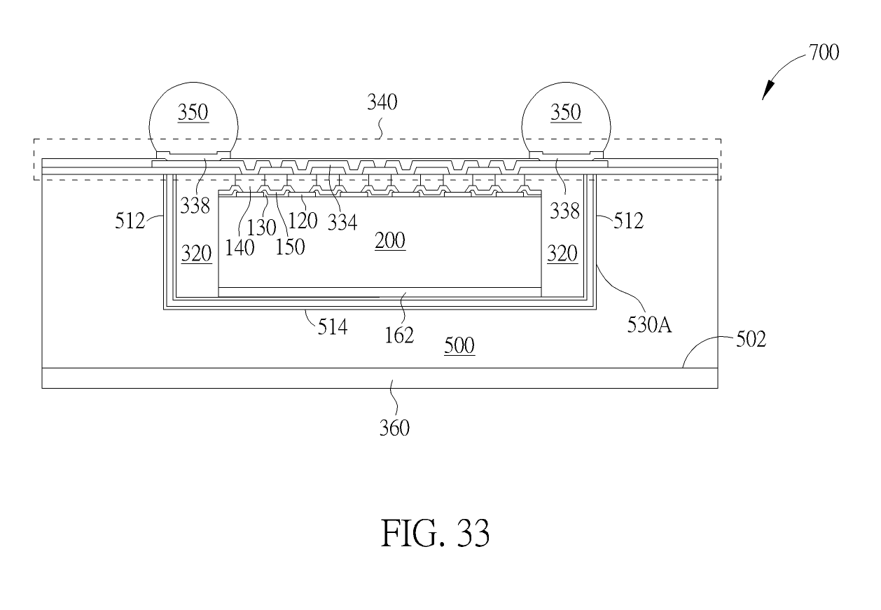

In a fourth embodiment of the present invention, the cavities 510 are formed on the substrate 500 by performing a plasma etching process instead of a wet chemical etching process. A semiconductor package 700 manufactured according to the fourth embodiment is illustrated in FIG. 33. The structure of the semiconductor package 700 is similar to that of the semiconductor package 600 shown in FIG. 32. The major difference between the semiconductor packages 600 and 700 is that the walls 512 of the cavity 510 of the semiconductor package 700 are substantially perpendicular to the bottom 514 of the cavity 510 of the semiconductor package 700.

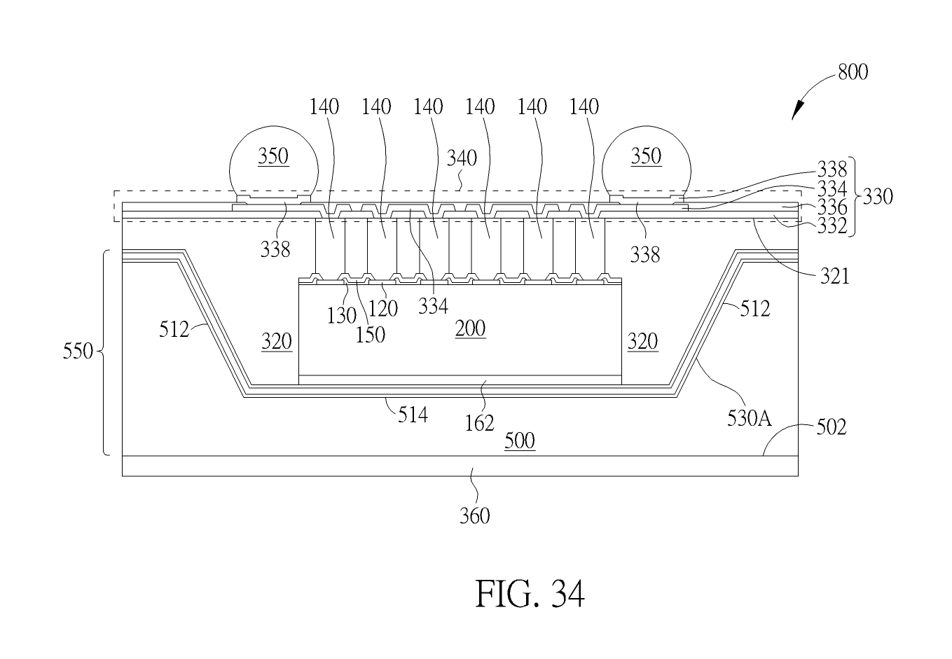

A semiconductor package 800 manufactured according to a fifth embodiment is illustrated in FIG. 34. The structure of the semiconductor package 800 is similar to that of the semiconductor package 600 shown in FIG. 32. In the semiconductor package 800, the pillar bumps 140 has a height greater than the height of the pillar bumps 140 in previous embodiments. The EMI shields 530A and the substrate 500 are covered by mold layer 320. The mold layer 320 may have been grinded to expose the pillar bumps 140 and form a grinded surface 321 if the pillar bumps 140 had been encapsulated by the mold layer 320. The pillar bumps 140 may be exposed and the grinded surface 321 may be formed without grinding the EMI shields 530A and the substrate 500 of the carrier 550. The interconnection structure 330 may be formed on the grinded surface 321 of the mold layer 320. The cover layer 360 may be formed on the second surface 502 of the substrate 500. The semiconductor package 800 is formed by sawing at least the interconnection structure 330, the mold layer 320 and the carrier 550. In some embodiments, the PI layers 332 and 336 of interconnection structure 330 may be sawed through by the sawing mechanism 410.

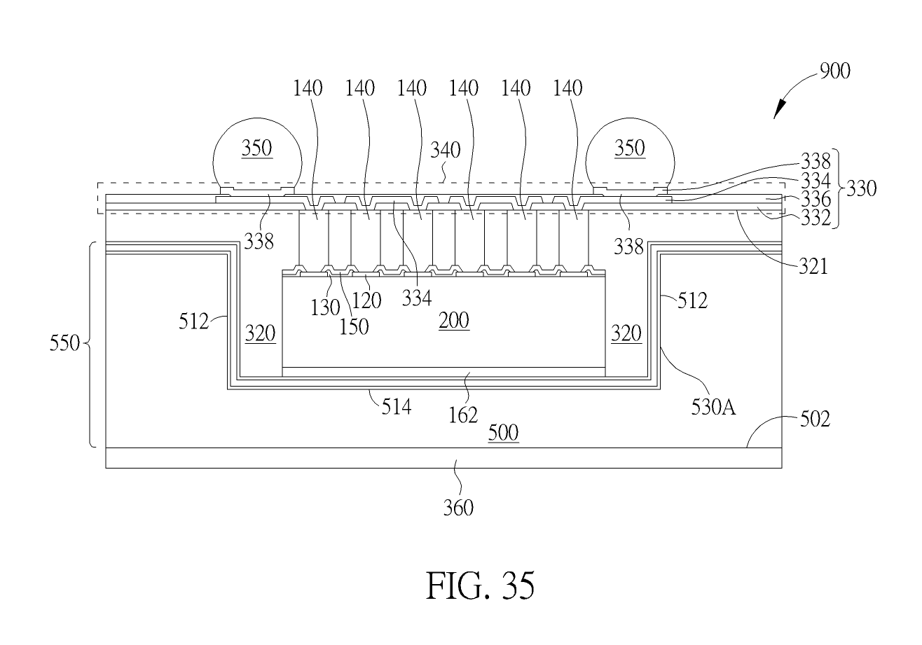

A semiconductor package 900 manufactured according to a sixth embodiment is illustrated in FIG. 35. The structure of the semiconductor package 900 is similar to that of the semiconductor package 800 shown in FIG. 34. The major differences between the semiconductor packages 800 and 900 are that the walls 512 of the cavity 510 of the semiconductor package 900 are substantially perpendicular to the bottom 514 of the cavity 510 of the semiconductor package 900. The mold layer 320 may have been grinded to expose the pillar bumps 140 and form a grinded surface 321 if the pillar bumps 140 had been encapsulated by the mold layer 320. The pillar bumps 140 may be exposed and the grinded surface 321 may be formed without grinding the carrier 550. The interconnection structure 330 may be formed on the grinded surface 321 of the mold layer 320. The cover layer 360 may be formed on the second surface 502 of the substrate 500. The semiconductor package 900 is formed by sawing at least the interconnection structure 330, the mold layer 320 and the carrier 550. In some embodiments, the PI layers 332 and 336 of interconnection structure 330 may be sawed through by the sawing mechanism 410.

According to the embodiments of the present invention, an adhesive layer is formed in wafer level. A semiconductor wafer is diced to forma plurality of chips, and each of the chips has an adhesive sheet diced from the adhesive layer. Before a molding process is performed, adhesive sheets of the chips may be cured to fasten the chips on a carrier. Because the chips may be fixed on the carrier by the cured adhesive sheets, the chips on the first surface would almost not be moved by the drag force of the molding compound. Accordingly, the yield of final semiconductor package would be improved. In addition, the semiconductor package may comprise an EMI shield for providing EMI protection.

Those skilled in the art will readily observe that numerous modifications and alterations of the device and method may be made while retaining the teachings of the invention. Accordingly, the above disclosure should be construed as limited only by the metes and bounds of the appended claims.

1. A method for forming semiconductor packages, comprising:
providing a semiconductor wafer;
forming an adhesive layer on a surface of the semiconductor wafer;
dicing the semiconductor wafer to form a plurality of chips, each of the chips having a plurality of pillar bumps and an adhesive sheet diced from the adhesive layer;
adhering the adhesive sheet of each of the chips to a first surface of a carrier, the carrier made of a single material and an electromagnetic interference (EMI) protection layer forming the first surface;
forming a mold layer contacting and encapsulating sides of the chips, sides of the plurality of pillar bumps of the chips, and the carrier;
grinding at least the mold layer to expose the plurality of pillar bumps and form a grinded surface;
forming an interconnection structure containing circuitries on the grinded surface, each of the circuitries being electrically connected to a plurality of pillar bumps of a corresponding chip; and
forming a plurality of semiconductor packages by sawing at least the interconnection structure and the mold layer, each of the semiconductor packages comprising at least one of the chips and a corresponding circuitry.

2. The method of claim 1, wherein adhering the adhesive sheet of each of the chips to the first surface of the carrier is curing the adhesive sheet of each of the chips after disposing the chips on the first surface of the carrier.

3. The method of claim 1, wherein the carrier has a plurality of cavities formed thereon.

4. The method of claim 3, wherein the electromagnetic interference (EMI) protection layer is a continuous layer covering walls and bottoms of the cavities;
wherein the adhesive sheet of each of the chips is permanently adhered to the continuous electromagnetic interference (EMI) protection layer.

5. The method of claim 4, wherein grinding at least the mold layer to expose the plurality of pillar bumps and form the grinded surface is grinding the mold layer and the carrier to expose the plurality of pillar bumps and form the grinded surface.

6. The method of claim 4, wherein the each of the semiconductor packages further comprises an EMI shield diced from the continuous EMI protection layer.

7. The method of claim 1, further comprising:
forming a cover layer on a second surface of the carrier;
wherein the plurality of semiconductor packages are formed by sawing the interconnection structure, the mold layer, the carrier and the cover layer.

8. The method of claim 1, wherein the each of the semiconductor packages further comprises an electromagnetic interference (EMI) shield diced from a continuous EMI protection layer of the carrier, and the adhesive sheet of the each of the chips is permanently adhered to a corresponding EMI shield.

9. The method of claim 1, wherein a thermal conductivity of the carrier is greater than a thermal conductivity of the semiconductor wafer.

10. The method of claim 1, wherein grinding at least the mold layer to expose the plurality of pillar bumps and form the grinded surface is performed without grinding the carrier.

11. A semiconductor package, comprising:
a carrier made of a single material and an electromagnetic interference (EMI) shield forming the first surface;
at least a chip, adhered on a first surface of the carrier by an adhesive sheet, and the chip having a plurality of pillar bumps;
a mold layer contacting and encapsulating sides of the chip, sides of the plurality of pillar bumps of the chip, and the carrier; and
an interconnection structure, formed on a grinded surface of the mold layer and electrically connected to the plurality of pillar bumps of the chip.

12. The semiconductor package of claim 11, wherein the interconnection structure comprises at least a polyimide layer and at least a redistribution layer.

13. The semiconductor package of claim 11 further comprising a cover layer formed on a second surface of the carrier.

14. The semiconductor package of claim 13, wherein the cover layer is formed by performing a screen printing process, a stencil printing or a lamination process.

15. The semiconductor package of claim 11, wherein the carrier has a cavity formed thereon.

16. The semiconductor package of claim 15, wherein the electromagnetic interference (EMI) shield covers walls and a bottom of the cavity, and the chip is permanently adhered on the EMI shield by the adhesive sheet.

17. The semiconductor package of claim 16, wherein the walls of the cavity are perpendicular to the bottom of the cavity.

18. The semiconductor package of claim 16, wherein the walls of the cavity slope towards the bottom of the cavity.

19. The semiconductor package of claim 11 further comprising a plurality of solder balls formed on the interconnection structure.

20. The semiconductor package of claim 11, wherein a thermal conductivity of the carrier is greater than a thermal conductivity of the chip.
